(19) United States
(12) Patent Application Publication
(10) Pub. No.: US 2026/0064151 A1
(43) Pub. Date: Mar. 5, 2026

(54) Device and Method of Operation Thereof

(71) Applicant: Taiwan Semiconductor Manufacturing Company, Ltd., Hsinchu (TW)

(72) Inventor: Shenggao Li, Hsinchu (TW)

(21) Appl. No.: 18/815,990

(22) Filed: Aug. 27, 2024

(51) Int. Cl. G06F 1/12; G06F 1/10; H01L 25/18; H01L 27/06; H03K 17/567; H03K 19/0185

(52) U.S. Cl. CPC G06F 1/12; G06F 1/10; H03K 17/567; H03K 19/01855; H10D 88/00

(57) ABSTRACT

A system includes a plurality of stacked semiconductor chips, one of which includes a distribution network, an output clock signal generator, a clock signal grid, a conductive layer. The distribution network generates a plurality of input clock signals and a plurality of first output clock signals, each corresponding to the input clock signal. The output clock signal generator generates a plurality of second output clock signals, each corresponding to the first output clock signal. The clock signal grid interconnects inputs or outputs of the distribution network and facilitates the substantially simultaneous arrival of the first output clock signals at the output clock signal generator. The conductive layer is formed over a surface of the first semiconductor chip and is connected to the clock signal grid.

### BACKGROUND

In modern semiconductor chip packaging technologies, there is a constant demand for higher performance and more compact designs. One way to achieve this is through a three-dimensional integrated circuit (3D-IC) or a chip-on-wafer-on-substrate (CoWoS). These technologies involve stacking semiconductor chips (also referred to as integrated circuits or dies) on top of each other. By doing so, they can improve the performance of the overall system due to the shorter interconnects between the stacked semiconductor chips, reducing latency. Additionally, this stacking approach minimizes the chip area on a package substrate. Instead of placing semiconductor chips side by side, stacking them can save space in directions where such space is limited, allowing for more compact designs.

### BRIEF DESCRIPTION OF THE DRAWINGS

Aspects of the present disclosure are best understood from the following detailed description when read with the accompanying figures:

FIG. 1 is a schematic block diagram illustrating an exemplary system in accordance with various embodiments of the present disclosure;

FIG. 2 is a schematic block/circuit diagram of an exemplary clock signal distribution tree in accordance with various embodiments of the present disclosure;

FIG. 3 is a schematic circuit/block diagram illustrating exemplary semiconductor chips in accordance with various embodiments of the present disclosure;

FIG. 4 is a flowchart of an exemplary method for synchronizing clock signals in accordance with various embodiments of the present disclosure;

FIG. 5 is a schematic circuit/block diagram illustrating another exemplary semiconductor chips in accordance with various embodiments of the present disclosure;

FIG. 6 is a schematic circuit/block diagram illustrating another exemplary semiconductor chips in accordance with various embodiments of the present disclosure;

FIG. 7 is a schematic sectional diagram illustrating another exemplary semiconductor chips in accordance with various embodiments of the present disclosure; and

FIG. 8 is a schematic sectional diagram illustrating another exemplary semiconductor chips in accordance with various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Stacking semiconductor chips (also referred to as integrated circuits or dies) on top of each other can reduce space and enhances performance. This method is used in packaging technologies such as three-dimensional integrated circuit (3D-IC) and chip-on-wafer-on-substrate (CoWoS). In embodiments, each semiconductor chip in a stack may generate its own clock signal. These clock signals may not be synchronized, which can result in communication errors during data transmission/reception between semiconductor chips. For example, if one semiconductor chip attempts to transmit data while the clock signal of the receiving semiconductor chip is not aligned, the data may be sampled at incorrect times. Such issues can be problematic in high-speed data communication, e.g., 4-32 Gbps. Systems and methods as described in certain examples herein mitigate this issue by enabling a semiconductor chip, instead of generating its own clock signal, to leverage the clock signal of another semiconductor chip.

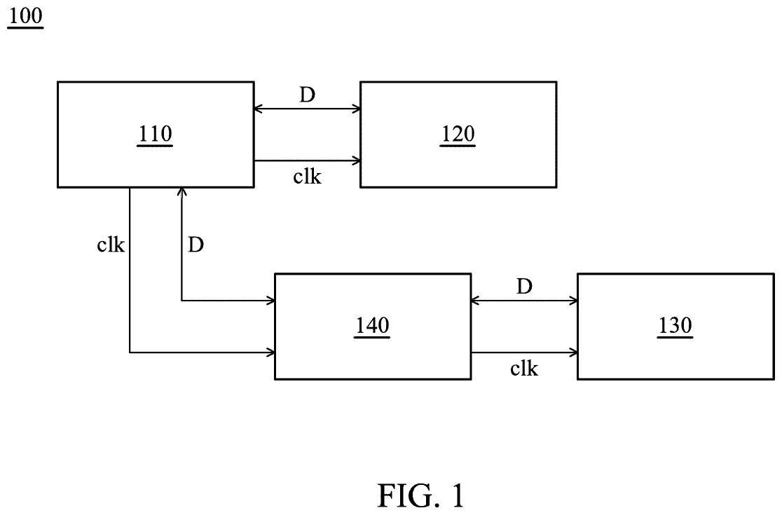

FIG. 1 is a schematic block diagram illustrating an exemplary system 100 in accordance with various embodiments of the present disclosure. As illustrated in FIG. 1, the example system 100 (e.g., a 3D-IC, CoWoS, or other systems employing different packaging technologies) includes a plurality of semiconductor chips, e.g., semiconductor chips 110-130, and one or more an interposers, e.g., interposer 140. The semiconductor chips 110-130 and the interposer 140 are mounted on a package substrate and are stacked on top of each other. The package substrate may be patterned with a plurality of conductive traces. These traces may be made of conductive materials, e.g., copper, facilitate electrical connections between various components of the device 100.

The semiconductor chip 110 generates its own clock signal (clk) and transmits a data signal (D) according, or in response, to the clock signal (clk). The semiconductor chip 120 is bonded to the semiconductor chip 110 and receives the data signal (D) in response the clock signal (clk). The interposer 140 interconnects the semiconductor chips 110, 130 and includes a redistribution layer (RDL), one or more through-substrate vias (TSVs), and/or one or more through-interposer vias (TIVs). The semiconductor chip 140 receives the data signal (D) in response the clock signal (clk). In certain embodiments, at least one of the semiconductor chips 120, 130 is further operable to transmit data to the semiconductor chip 110. In such certain embodiments, the semiconductor chip 110 is further operable to receive the data from the at least one of the semiconductor chips 120, 130.

From the above description, the semiconductor chip 110 serves as the source of the clock signal (clk) for the semiconductor chips 120, 130. This ensures that the operations of the semiconductor chips 120, 130 are substantially synchronized with those of the semiconductor chip 110. The construction as such prevents communication errors that may otherwise occur due to timing discrepancies during data transmission/reception between the semiconductor chips 110, 120 and between the semiconductor chips 110, 130.

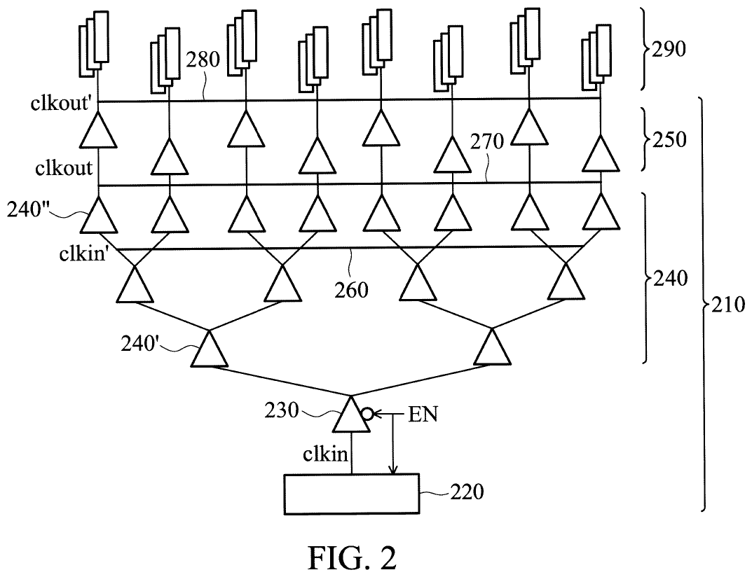

FIG. 2 is a schematic block/circuit diagram of an exemplary clock signal distribution tree 210 of a semiconductor chip, e.g., semiconductor chip 110, that distributes clock signals (clkin, clkin′, clkout, clkout′) throughout the semiconductor chip 110 in accordance with various embodiments of the present disclosure. As illustrated in FIG. 2, the example clock signal distribution tree 210 includes an input clock signal (clkin) generator 220, a gating circuit 230, a distribution network 240, an output clock signal (clkout) generator 250, and a plurality of clock signal grids 260-280. In this exemplary embodiment, the input clock signal (clkin) generator 220 includes a phase lock loop (PLL) and generates an input clock signal (clkin) (e.g., that corresponds to an input clock signal received from an input clock signal generator external to the semiconductor chip 110). In certain embodiments, the input clock signal (clkin) generator 220 receives an enable signal (EN), e.g., received from an enable signal (EN) generator external to or built-in within the semiconductor chip 110. In such certain embodiments, when the enable signal (EN) is active (e.g., logical ‘1’ or high), the input clock signal (clkin) generator 220 is permitted to generate the input clock signal (clkin). Otherwise, i.e., when the enable signal (EN) is inactive (e.g., logical ‘0’ or low), the input clock signal (clkin) generator 220 is inhibited from generating the input clock signal (clkin).

The gating circuit 230 includes one or more components (such as transistors, logic gates, or other circuits for gating purposes), receives the enable signal (EN), and controls the passage of the input clock signal (clkin) based on the enable signal (EN). For example, when the enable signal (EN) is active (e.g., logical ‘1’ or high), the input clock signal (clkin) propagates through the gating circuit 230. Conversely, when the enable signal (EN) is inactive (e.g., logical ‘0’ or low), the gating circuit 230 blocks the input clock signal (clkin) from reaching the distribution network 240.

In an alternative embodiment, the input clock signal (clkin) generator 220 receives a first enable signal and the gating circuit 230 receives a second enable signal different from the first enable signal. In such an alternative embodiment, at least one of the first and second enable signals is received from an enable signal (EN) generator external to or built-in within the semiconductor chip 110.

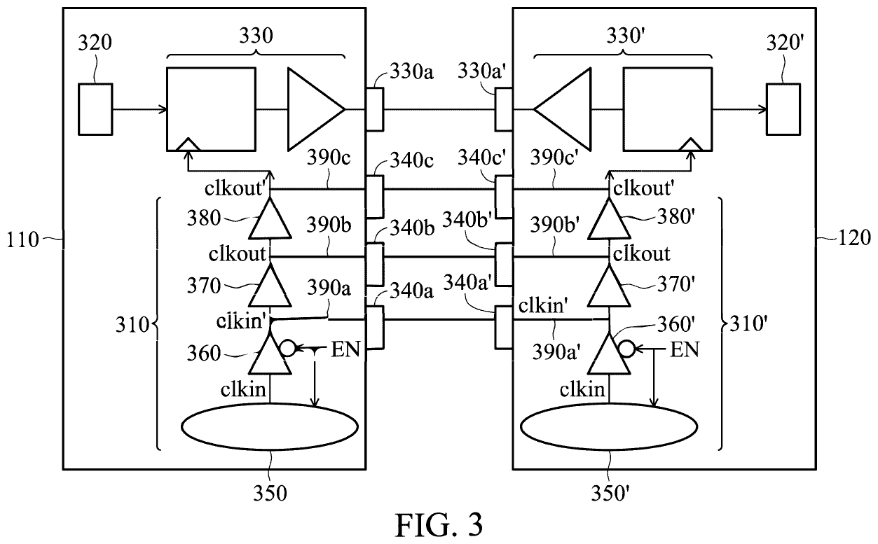

The distribution network 240 ensures that the input clock signal (clkin) has a sufficient strength to drive the loads 290 (e.g., data signal transmitter 330 of FIG. 3) of the semiconductor chip 110. For example, the distribution network 240 includes one or more first stages of clock tree cells (only one of the clock tree cells is labeled as 240′ in FIG. 2) and one or more second stages of the clock tree cells (only one of the clock tree cells is labeled as 240″ in FIG. 2). Each clock tree cell 240′ includes one or more buffer circuits and generates an input clock signal (clkin′) that corresponds to the input clock signal (clkin). Each clock tree cell 240″ includes one or more buffer circuits and generates an output clock signal (clkout) that corresponds to the input clock signal (clkin′). The output clock signal (clkout) generator 250 drives the loads 290, includes a plurality of drivers, each connected to a respective load 290, and generates a plurality of output clock signals (clkout′), each corresponding to a respective output clock signal (clkout).

The clock signal grid 260 interconnects the inputs/outputs of the distribution network 240, substantially synchronizing the input clock signals (clkin′) with each other. Similarly, the clock signal grid 270 interconnects the outputs of the distribution network 240, facilitating the substantially simultaneous arrival of the output clock signals (clkout) at the inputs of the output clock signal (clkout) generator 250. Additionally, the clock signal grid 280 interconnects the outputs of the output clock signal (clkout) generator 250, ensuring that that output clock signals (clkout′) reach the loads 290 at substantially the same time.

FIG. 3 is a schematic circuit/block diagram illustrating exemplary semiconductor chips (e.g., semiconductor chips 110, 120) in accordance with various embodiments of the present disclosure. As illustrated in FIG. 3, the example semiconductor chip 110 includes a clock signal distribution tree 310, a data signal generator 320, a data signal transmitter 330, and a plurality of interconnects 330a, 340a-340c. The clock signal distribution tree 310 distributes clock signals (clkin, clkin′, clkout, clkout′) throughout the semiconductor chip 110 and includes an input clock signal (clkin) generator 350, a gating circuit 360, a distribution network 370, an output clock signal (clkout) generator 380, and a plurality of clock signal grids 390a-390c. In this exemplary embodiment, the input clock signal (clkin) generator 350 includes a phase lock loop (PLL) and generates an input clock signal (clkin) (e.g., that corresponds to an input clock signal received from an input clock signal generator external to the semiconductor chip 110). In certain embodiments, the input clock signal (clkin) generator 350 receives an enable signal (EN), e.g., received from an enable signal (EN) generator external to or built-in within the semiconductor chip 110. In such certain embodiments, when the enable signal (EN) is active (e.g., logical ‘1’ or high), the input clock signal (clkin) generator 350 is permitted to generate the input clock signal (clkin). Otherwise, i.e., when the enable signal (EN) is inactive (e.g., logical ‘0’ or low), the input clock signal (clkin) generator 350 is inhibited from generating the input clock signal (clkin).

The gating circuit 360 includes one or more components (such as transistors, logic gates, or other circuits for gating purposes), receives the enable signal (EN), and controls the passage of the input clock signal (clkin) based on the enable signal (EN). For example, when the enable signal (EN) is active (e.g., logical ‘1’ or high), the input clock signal (clkin) propagates through the gating circuit 360. Conversely, when the enable signal (EN) is inactive (e.g., logical ‘0’ or low), the gating circuit 360 blocks the input clock signal (clkin) from reaching the distribution network 370.

In an alternative embodiment, the input clock signal (clkin) generator 350 receives a first enable signal and the gating circuit 360 receives a second enable signal different from the first enable signal. In such an alternative embodiment, at least one of the first and second enable signals is received from an enable signal (EN) generator external to or built-in within the semiconductor chip 110.

The distribution network 370 ensures that the input clock signal (clkin) has a sufficient strength to drive loads, e.g., data signal transmitter 330, of the semiconductor chip 110. For example, the distribution network 370 includes one or more first stages of clock tree cells (e.g., clock tree cells 240′ in FIG. 2) and one or more second stages of the clock tree cells (e.g., clock tree cells 240″ in FIG. 2). Each clock tree cell in the first stages includes one or more buffer circuits and generates an input clock signal (clkin′) that corresponds to the input clock signal (clkin). Each clock tree cell in the second stages includes one or more buffer circuits and generates an output clock signal (clkout) that corresponds to the input clock signal (clkin′). The output clock signal (clkout) generator 380 drives the loads 330, includes a plurality of drivers, each connected to a respective load 330, and generates a plurality of output clock signals (clkout′), each corresponding to a respective output clock signal (clkout).

The clock signal grid 390a interconnects the inputs/outputs of the distribution network 370, substantially synchronizing the input clock signals (clkin′) with each other. Similarly, the clock signal grid 390b interconnects the outputs of the distribution network 370, facilitating the substantially simultaneous arrival of the output clock signals (clkout) at the inputs of the output clock signal (clkout) generator 380. Additionally, the clock signal grid 390c interconnects the outputs of the output clock signal (clkout) generator 380, ensuring that that output clock signals (clkout′) reach the loads 330 at substantially the same time.

Each interconnect 340a-340c is formed over a surface of the semiconductor chip 110 and is connected to the respective clock signal grid 390a-390c. The interconnects 340a-340c can be in the form of micro-bumps, solder balls, copper pillars, a combination of metal and dielectric interconnects, other interconnects created by, e.g., hybrid bonding, tape-automated bonding (TAB), wire bonding, flip-chip bonding, other suitable interconnects, or combinations thereof. The data signal generator 320 (e.g., a central processing unit or CPU, a graphics processing unit or GPU, a math co-processor, a.k.a. a floating-point unit or FPU, and the like) generates an input data signal. In response to the output clock signal (clkout′), the data signal transmitter 330 transmits an output data signal, e.g., data signal (D) of FIG. 1, that corresponds to the input data signal. In this exemplary embodiment, the data signal transmitter 330 includes a d-type flip-flop that stores and transfers data and a data signal amplifier that generates an amplified version of the output data signal at the interconnect 330a. In certain embodiments, the interconnects 330a, 340a-340c constitute a conductive layer formed over a front or back surface of the semiconductor chip 110.

Similarly, the example semiconductor chip 120 includes a clock signal distribution tree 310′, a data signal generator 320′, a data signal receiver 330′, and a plurality of interconnects 330a′, 340a′-340c′. The clock signal distribution tree 310′ distributes clock signals (clkin, clkin′, clkout, clkout′) throughout the semiconductor chip 120 and includes an input clock signal (clkin) generator 350′, a gating circuit 360′, a distribution network 370′, an output clock signal (clkout) generator 380′, and a plurality of clock signal grids 390a′-390c′. In this exemplary embodiment, the input clock signal (clkin) generator 350′ includes a phase lock loop (PLL) and generates an input clock signal (clkin) (e.g., that corresponds to an input clock signal received from an input clock signal generator external to the semiconductor chip 120). In certain embodiments, the input clock signal (clkin) generator 350′ receives an enable signal (EN), e.g., received from an enable signal (EN) generator external to or built-in within the semiconductor chip 120. In such certain embodiments, when the enable signal (EN) is active (e.g., logical ‘1’ or high), the input clock signal (clkin) generator 350′ is permitted to generate the input clock signal (clkin). Otherwise, i.e., when the enable signal (EN) is inactive (e.g., logical ‘0’ or low), the input clock signal (clkin) generator 350′ is inhibited from generating the input clock signal (clkin).

The gating circuit 360′ includes one or more components (such as transistors, logic gates, or other circuits for gating purposes), receives the enable signal (EN), and controls the passage of the input clock signal (clkin) based on the enable signal (EN). For example, when the enable signal (EN) is active (e.g., logical ‘1’ or high), the input clock signal (clkin) propagates through the gating circuit 360′. Conversely, when the enable signal (EN) is inactive (e.g., logical ‘0’ or low), the gating circuit 360′ blocks the input clock signal (clkin) from reaching the distribution network 370′.

In an alternative embodiment, the input clock signal (clkin) generator 350′ receives a first enable signal and the gating circuit 360′ receives a second enable signal different from the first enable signal. In such an alternative embodiment, at least one of the first and second enable signals is received from an enable signal (EN) generator external to or built-in within the semiconductor chip 120.

The distribution network 370′ ensures that the input clock signal (clkin) has a sufficient strength to drive loads, e.g., data signal receiver 330′, of the semiconductor chip 120. For example, the distribution network 370′ includes one or more first stages of clock tree cells (e.g., clock tree cells 240′ in FIG. 2) and one or more second stages of the clock tree cells (e.g., clock tree cells 240″ in FIG. 2). Each clock tree cell in the first stages includes one or more buffer circuits and generates an input clock signal (clkin′) that corresponds to the input clock signal (clkin). Each clock tree cell in the second stages includes one or more buffer circuits and generates an output clock signal (clkout) that corresponds to the input clock signal (clkin′). The output clock signal (clkout) generator 380′ drives the loads 330′, includes a plurality of drivers, each connected to a respective load 330′, and generates a plurality of output clock signals (clkout′), each corresponding to a respective output clock signal (clkout).

The clock signal grid 390a′ interconnects the inputs/outputs of the distribution network 370′, substantially synchronizing the input clock signals (clkin′) with each other. Similarly, the clock signal grid 390b′ interconnects the outputs of the distribution network 370′, facilitating the substantially simultaneous arrival of the output clock signals (clkout) at the inputs of the output clock signal (clkout) generator 380′. Additionally, the clock signal grid 390c′ interconnects the outputs of the output clock signal (clkout) generator 380′, ensuring that that output clock signals (clkout′) reach the loads 330′ at substantially the same time.

Each interconnect 340a′-340c′ is formed over a surface of the semiconductor chip 120 and is connected to the respective clock signal grid 390a′-390c′. The interconnects 340a′-340c′ are bonded to the interconnects 340a-340c, respectively. The interconnects 340a-340c can be in the form of micro-bumps, solder balls, copper pillars, a combination of metal and dielectric interconnects, other interconnects created by, e.g., hybrid bonding, tape-automated bonding (TAB), wire bonding, flip-chip bonding, other suitable interconnects, or combinations thereof. In response to the output clock signal (clkout′), the data signal receiver 330′ receives an output data signal transmitted by the semiconductor chip 110. In this exemplary embodiment, the data signal receiver 330′ includes a data signal amplifier that generates an amplified version of the output data signal at the interconnect 330a′ and a flip-flop, such as a d-type flip-flop, that stores and transfers data in response to the output clock signal (clkout′). In certain embodiments, the interconnects 330a′, 340a′-340c′ constitute a conductive layer formed over a front or back surface of the semiconductor chip 120. The data signal generator 320′ may be a memory device, such as a random access memory (RAM), that stores data therein when written and that outputs/generates data when read. Other data signal generators that output data are contemplated herein. In certain embodiments, the semiconductor chip 120 is further operable to transmit data. In such certain embodiments, the semiconductor chip 110 is further operable to receive data transmitted by the semiconductor chip 120.

From the above description, the semiconductor chip 110 serves as the source of clock signals (clkin, clkin′, clkout, clkout′) for the semiconductor chip 120. This ensures that the operations of the semiconductor chip 120 are substantially synchronized with those of the semiconductor chip 110. The construction as such prevents communication errors that may otherwise occur due to timing discrepancies during data transmission/reception between the semiconductor chips 110, 120.

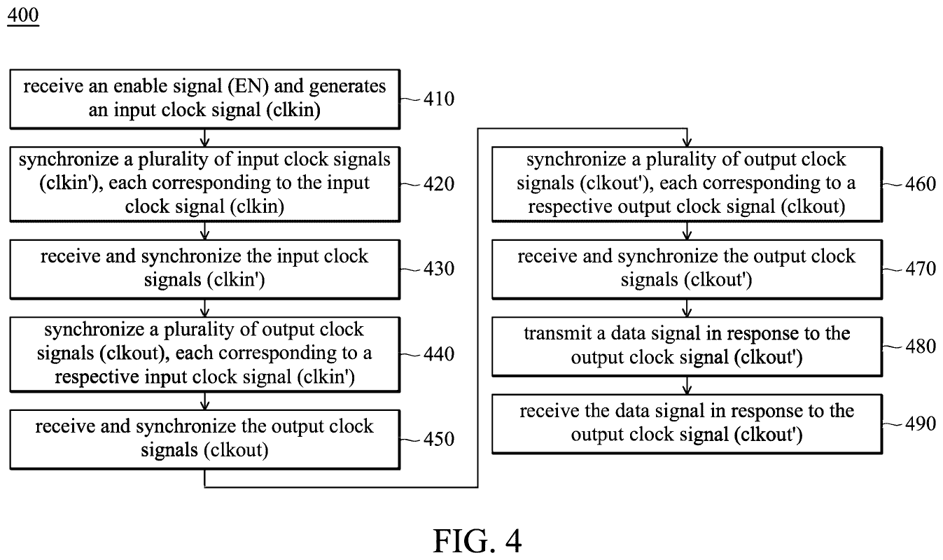

FIG. 4 is a flowchart of an exemplary method 400 for synchronizing clock signals (clkin, clkin′, clkout, clkout′) between semiconductor chips, e.g., semiconductor chips 110, 120, of a system, e.g., system 100, in accordance with various embodiments of the present disclosure. The example method 400 will now be described with further reference to FIGS. 1-3 for ease of understanding. It is understood that the method 400 is applicable to structures other than those of FIGS. 1-3. Further, it is understood that additional operations can be provided before, during, and after the method 400, and some of the operations described below can be replaced or eliminated, in an alternative embodiment of the method 400.

In operation 410, the semiconductor chip 110 receives an enable signal (EN) that is a logical ‘1’ or high and thus generates an input clock signal (clkin) (e.g., that corresponds to an input clock signal received from an input clock signal generator external to the semiconductor chip 110). At this time, the semiconductor chip 120 receives an enable signal (EN) that is a logical ‘0’ or low and is thus disabled from generating and/or distributing clock signals (clkin, clkin′, clkout, clkout′). In operation 420, the semiconductor chip 110 distributes a plurality of input clock signals (clkin′), each corresponding to the input clock signal (clkin), and synchronizes the input clock signals (clkin′). In operation 430, the semiconductor chip 120 receives and synchronizes the input clock signals (clkin′).

Subsequently, in operation 440, the semiconductor chip 110 generates a plurality of output clock signals (clkout), each corresponding to a respective input clock signal (clkin′), and synchronizes the output clock signals (clkout). In operation 450, the semiconductor chip 120 receives and synchronizes the output clock signals (clkout). Next, in operation 460, the semiconductor chip 110 generates a plurality of output clock signals (clkout′), each corresponding to a respective output clock signal (clkout), and synchronizes the output clock signals (clkout′). In operation 470, the semiconductor chip 120 receives and synchronizes the output clock signals (clkout′). In operation 480, the semiconductor chip 110 generates and transmits a data signal, e.g., data signal (D), in response to the output clock signals (clkout′). In operation 490, the semiconductor chip 120 receives the data signal (D) transmitted by the semiconductor chip 110 in response to the output clock signals (clkout′).

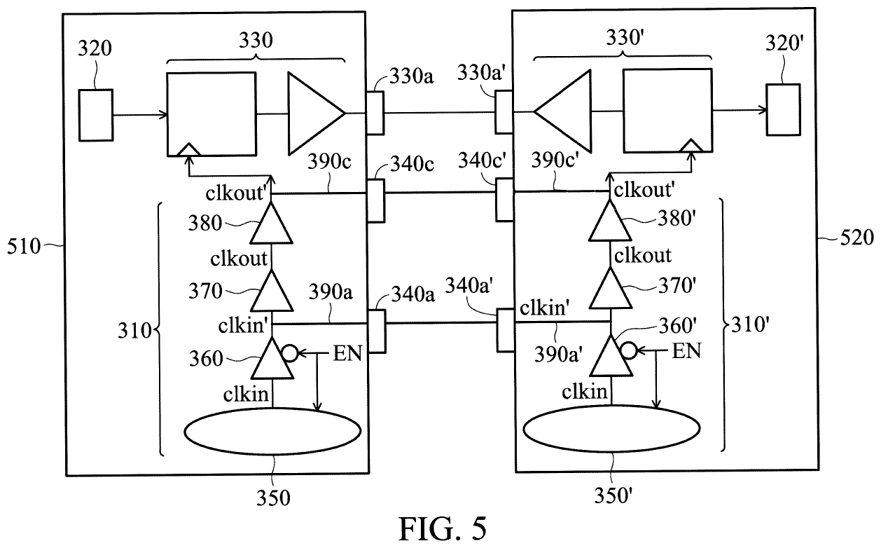

Although each semiconductor chip 110, 120 is exemplified with three clock signal grids 390a-390c, 390a′-390c′, it should be understood that, after reading this disclosure, the number of the clock signal grids of the semiconductor chip 110, 120 may be increased or decreased as desired. For example, FIG. 5 is a schematic circuit/block diagram illustrating another exemplary semiconductor chips 510, 520 in accordance with various embodiments of the present disclosure. As illustrated in FIG. 5, the example semiconductor chip 510, 520 differs from the semiconductor chip 110, 120 in that the semiconductor chip 510, 520 is dispensed with the clock signal grid 390b, 390b′. In this exemplary embodiment, the semiconductor chip 510, 520 synchronizes the clock signals (clkin′, clkout′), but not the clock signals (clkout).

Because the operations of the semiconductor chips 510, 520 are similar to those described above in connection with the semiconductor chips 110, 120, a detailed description of the same is omitted herein for the sake of brevity.

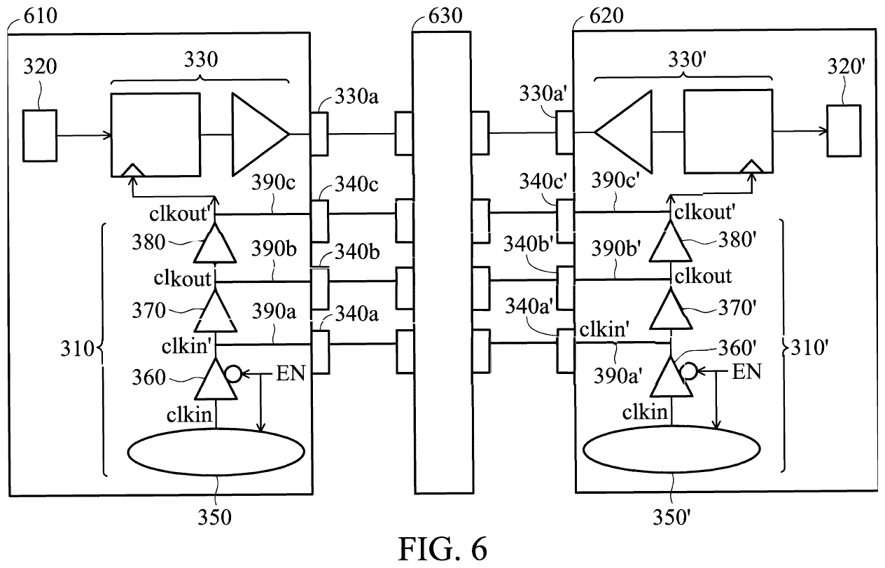

FIG. 6 is a schematic circuit/block diagram illustrating another exemplary semiconductor chips 610, 620 in accordance with various embodiments of the present disclosure. As illustrated in FIG. 6, the example semiconductor chip 610, 620 differs from the semiconductor chip 110, 120 in that the semiconductor chip 610, 620 are interconnected by an interposer 630. For example, interposer 630 includes first and second sets of interconnects. Each interconnects in the first set is connected to a respective interconnect 330a, 340a-340c, whereas each interconnect in the second set is connected to a respective interconnect 330a′, 340a′-340c′. The interposer includes an RDL, one or more TSVs, and/or one or more TIVs connecting the interconnects in the first set to the interconnects in the second sets, respectively,.

Because the operations of the semiconductor chips 610, 620 are similar to those described above in connection with the semiconductor chips 110, 120, a detailed description of the same is omitted herein for the sake of brevity.

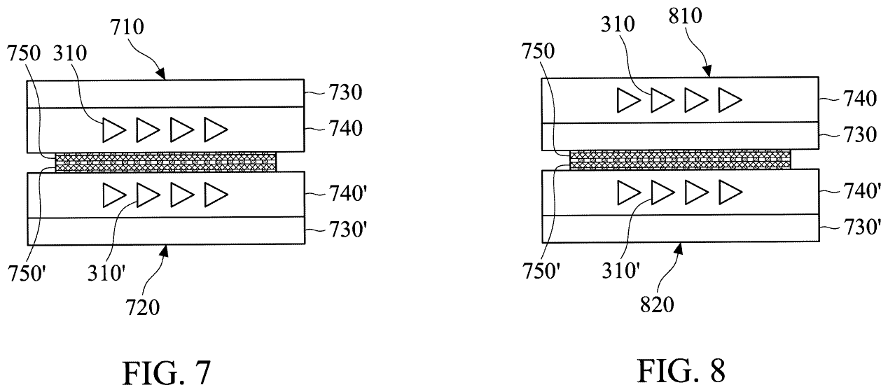

FIG. 7 is a schematic sectional diagram illustrating another exemplary semiconductor chips 710, 720 in accordance with various embodiments of the present disclosure. As illustrated in FIG. 7, the example semiconductor chip 710 includes a chip substrate 730, a device layer 740, and a conductive layer 750. Examples of materials for the chip substrate 730 include silicon, germanium, III-V semiconductor materials, other suitable semiconductor materials, and their alloys. The device layer 740 is formed over the chip substrate 730 and includes a plurality of chip components (e.g., passive electronic components, such as resistors, capacitors, and inductors, as well as active electronic components, such as transistors) and horizontal and vertical metal lines interconnecting the chip components. For example, with further reference to FIG. 3, the device layer 740 includes the clock signal distribution tree 310, the data signal generator 320, the data signal transmitter 330, and at least one of the clock signal grids 390a-390c. The conductive layer 750 includes the interconnects 340a-340c, is formed over a front surface of the semiconductor chip 710, and is connected to the device layer 740.

Similarly, the example semiconductor chip 720 includes a chip substrate 730′, a device layer 740′, and a conductive layer 750′. Examples of materials for the chip substrate 730 include silicon, germanium, III-V semiconductor materials, other suitable semiconductor materials, and their alloys. The device layer 740′ is formed over the chip substrate 730′ and includes a plurality of chip components (e.g., passive electronic components, such as resistors, capacitors, and inductors, as well as active electronic components, such as transistors) and horizontal and vertical metal lines interconnecting the chip components. For example, with further reference to FIG. 3, the device layer 740′ includes the clock signal distribution tree 310′, the data signal generator 320′, the data signal receiver 330′, and at least one of the clock signal grids 390a′-390c′. The conductive layer 750′ includes the interconnects 340a′-340c′, is formed over a front surface of the semiconductor chip 720 and connected between the device layer 740′ and the conductive layer 750.

FIG. 8 is a schematic sectional diagram illustrating another exemplary semiconductor chips 810, 820 in accordance with various embodiments of the present disclosure. As illustrated in FIG. 8, the exemplary semiconductor chip 810 differs from the semiconductor chip 710 in that the conductive layer 750, instead of being formed over the front surface, is formed over the back surface of the semiconductor chip 810. The conductive layer 750′ of the semiconductor chip 820 is connected or bonded to the conductive layer 750.

In an embodiment, a system comprises a plurality of stacked semiconductor chips. A semiconductor chip of the plurality of semiconductor chips includes an input clock signal generator, a distribution network, an output clock signal generator, a clock signal grid, a conductive layer, and a data signal transmitter or receiver. The input clock signal generator generates a first input clock signal. The distribution network generates a plurality of second input clock signals, each corresponding to the first input clock signal, and a plurality of first output clock signals, each corresponding to the second input clock signal. The output clock signal generator generates a plurality of second output clock signals, each corresponding to the first output clock signal. The clock signal grid interconnects the inputs or outputs of the distribution network and facilitates the substantially simultaneous arrival of the first output clock signals at the output clock signal generator. The conductive layer is formed over a surface of the first semiconductor chip and connected to the clock signal grid. The data signal transmitter or receiver transmits or receives a data signal in response to the second output clock signal.

In another embodiment, a device comprises a semiconductor chip that includes an input clock signal generator, a distribution network, an output clock signal generator, a clock signal grid, and a conductive layer. The input clock signal generator generates a first input clock signal. The distribution network generates a plurality of second input clock signals, each corresponding to the first input clock signal, and a plurality of first output clock signals, each corresponding to the second input clock signal. The output clock signal generator generates a plurality of second output clock signals, each corresponding to the first output clock signal. The clock signal grid interconnects inputs or outputs of the distribution network and facilitates the substantially simultaneous arrival of the output clock signals at the output clock signal generator. The conductive layer is formed over a surface of the semiconductor chip and connected to the clock signal grid.

In another embodiment, a method for synchronizing first and second semiconductor chips comprises: the first semiconductor chip generating a first input clock signal; the first semiconductor chip distributing a plurality of second input clock signals, each corresponding to the first input clock signal; the first semiconductor chip synchronizing the second input clock signals; and the second semiconductor chip, bonded to the first semiconductor chip, receiving and synchronizing the second input clock signals.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A system comprising:
a plurality of stacked semiconductor chips, wherein a first semiconductor chip of the plurality of semiconductor chips includes:
an input clock signal generator configured to generate a first input clock signal;
a distribution network configured to generate a plurality of second input clock signals, each corresponding to the first input clock signal, and a plurality of first output clock signals, each corresponding to the second input clock signal;
an output clock signal generator configured to generate a plurality of second output clock signals, each corresponding to the first output clock signal;
a first clock signal grid interconnecting inputs or outputs of the distribution network and configured to facilitate the substantially simultaneous arrival of the first output clock signals at the output clock signal generator;
a conductive layer formed over a surface of the first semiconductor chip and connected to the first clock signal grid; and
a data signal transmitter or receiver configured to transmit or receive a data signal in response to the second output clock signal.

2. The system of claim 1, further comprising:
a second clock signal grid connected to the distribution network and configured to synchronized the second input clock signals; and
a third clock signal grid connected to the output clock signal generator and configured to synchronized the second output clock signals.

3. The system of claim 1, further comprising a gating circuit connected between the input clock signal generator and the distribution network and configured to receive an enable signal and to allow or inhibit the passage of the input clock signal based on the enable signal.

4. The system of claim 1, wherein the input clock signal generator is further configured to receive an enable signal and to allow or inhibit the generation of the input clock signal based on the enable signal.

5. The system of claim 1, further comprising a second semiconductor chip including:
an input clock signal generator configured to generate a third input clock signal;
a distribution network configured to generate a plurality of fourth input clock signal, each corresponding to the third input clock signal, and a plurality of third output clock signals, each corresponding to the fourth input clock signal;
an output clock signal generator configured to generate a plurality of fourth output clock signals, each corresponding to the third output clock signal;
a clock signal grid interconnecting the inputs or outputs of the distribution network of the second semiconductor chip and configured to facilitate the substantially simultaneous arrival of the third output clock signals at the output clock signal generator; and
a micro-bump formed over an outer surface of the second semiconductor chip and connected to the first clock signal grid of the second semiconductor chip.

6. The system of claim 5, wherein the second semiconductor chip further includes:
a data signal generator configured to generate a data signal; and
a data signal transmitter configured to transmit the data signal in response to the fourth output clock signal.

7. The system of claim 5, further comprising:
a second clock signal grid connected to the distribution network and configured to synchronized the fourth input clock signals; and
a third clock signal grid connected to the output clock signal generator and configured to synchronized the fourth output clock signals.

8. The system of claim 5, further comprising a gating circuit connected between the input clock signal generator of the second semiconductor chip and the distribution network of the second semiconductor chip and configured to receive an enable signal and to allow or inhibit the passage of the first input clock signal.

9. The system of claim 5, wherein the input clock signal generator of the second semiconductor chip is further configured to receive an enable signal and to allow or inhibit the generation of the input clock signal.

10. A device comprising:
a semiconductor chip including:
an input clock signal generator configured to generate a first input clock signal;
a distribution network configured to generate a plurality of second input clock signals, each corresponding to the first input clock signal, and a plurality of first output clock signals, each corresponding to the second input clock signal;
an output clock signal generator configured to generate a plurality of second output clock signals, each corresponding to the first output clock signal;
a first clock signal grid interconnecting inputs or outputs of the distribution network and configured to facilitate the substantially simultaneous arrival of the first output clock signals at the output clock signal generator; and
a conductive layer formed over a surface of the semiconductor chip and connected to the first clock signal grid.

11. The device of claim 10, further comprising a data signal generator configured to generate a data signal.

12. The device of claim 10, further comprising a data signal receiver configured to receive a data signal in response to the output clock signal.

13. The device of claim 10, further comprising:
a second clock signal grid connected to the distribution network and configured to synchronized the second input clock signals; and
a third clock signal grid connected to the output clock signal generator and configured to synchronized the second output clock signals.

14. The device of claim 10, further comprising a gating circuit connected between the input clock signal generator and the distribution network and configured to receive an enable signal and to allow or inhibit the passage of the input clock signal based on the enable signal.

15. The device of claim 10, wherein the input clock signal generator is further configured to receive an enable signal and to allow or inhibit the generation of the input clock signal based on the enable signal.

16. A method for synchronizing a first semiconductor chip and a second semiconductor chip, the method comprising:
the first semiconductor chip generating a first input clock signal;
the first semiconductor chip distributing a plurality of second input clock signals, each corresponding to the first input clock signal;
the first semiconductor chip synchronizing the second input clock signals; and
the second semiconductor chip, bonded to the first semiconductor chip, receiving and synchronizing the second input clock signals.

17. The method of claim 16, further comprising:
the first semiconductor chip generating a plurality of first output clock signals, each corresponding to the second input clock signal;
the first semiconductor chip synchronizing the plurality of first output clock signals; and
the second semiconductor chip receiving and synchronizing the first output clock signals.

18. The method of claim 17, further comprising:
the first semiconductor chip generating a plurality of second output clock signals, each corresponding to the first output clock signal;
the first semiconductor chip synchronizing the second output clock signals; and
the second semiconductor chip receiving and synchronizing the second output clock signals.

19. The method of claim 16, further comprising:
receiving an enable signal; and
allowing or inhibiting the passage of the input clock signal based on the enable signal.

20. The method of claim 16, further comprising:
receiving an enable signal; and
allowing or inhibiting the generation of the input clock signal based on the enable signal.
